(19) United States
(12) Patent Application Publication
(10) Pub. No.: US 2013/0256689 A1
(43) Pub. Date: Oct. 3, 2013

(54) NANOWIRE-BASED OPTOELECTRONIC SEMICONDUCTOR STRUCTURE AND METHOD OF MANUFACTURE OF SUCH A STRUCTURE

(71) Applicant: COMMISSARIAT A L'ENERGIE ATOMIQUE ET AUX ENE ALT, Paris (FR)

(72) Inventors: Emilie POUGEOISE, Grenoble (FR); Anne-Laure BAVENCOVE, Grenoble (FR); William VANDENDAELE, Grenoble (FR)

(73) Assignee: COMMISSARIAT A L'ENERGIE ATOMIQUE ET AUX ENE ALT, Paris (FR)

(21) Appl. No.: 13/851,517

(22) Filed: Mar. 27, 2013

Related U.S. Application Data
(60) Provisional application No. 61/642,040, filed on May 3, 2012.

(30) Foreign Application Priority Data
Apr. 2, 2012 (FR) 12 53011

(51) Int. Cl. H01L 31/0224; H01L 33/40

(52) U.S. Cl. CPC H01L 31/022408; H01L 33/40
USPC 257/76; 438/46; 438/93

(57) ABSTRACT

The invention concerns an optoelectronic semiconductor structure (100) including a semiconductor substrate (110) including a first face (111), a nucleation layer (120) and a nanowire (160) in contact with the nucleation layer. The nucleation layer (120) covers a portion of the first face (111) which is called the “nucleation” face, and where the portion (114) of the first face (111) not covered by the nucleation layer (120) is called the “free” portion. The structure also includes a conducting layer (141) in contact with the free portion (114) of the substrate (110), where the said conducting layer is also in contact with the nanowire over the perimeter of the nanowire (160). The invention also concerns a method of manufacture of such a structure (100).

### TECHNICAL FIELD

The invention relates to the field of detection, measurement and emission of electromagnetic radiation and to the devices allowing detection, measurement or emission of electromagnetic radiation.

The past ten years have seen many developments in optoelectronics and the devices deriving from it. Such devices use semiconductor structures which are suitable for detection, measurement or emission of electromagnetic radiation.

Among these structures, nanowire-based semiconductor structures show great potential as regards the achievable efficiencies, whether in terms of reception, in the case of detection and measurement, or of emission, of electromagnetic radiation. These efficiencies are also sufficiently substantial to envisage using such structures in photovoltaic applications.

Such structures, whether dedicated to detection, measurement or emission of electromagnetic radiation, or to photovoltaic applications, can be more generally called optoelectronic structures.

An optoelectronic structure, above and in the remainder of the document, is understood to mean every type of semiconductor structure suitable for converting from an electrical signal into electromagnetic radiation, or vice versa.

The invention relates more particularly to a method of manufacture of at least one semiconductor nanowire, and to an optoelectronic semiconductor structure.

### STATE OF THE PRIOR ART

The industrial development and sale of nanowire-based optoelectronic structures still remain very limited, due to a number of technological barriers.

Among these technological barriers, electrical losses relating to the connection and the polarisation of the nanowires may be mentioned.

Indeed, a nanowire-based optoelectronic semiconductor structure generally includes:
a semiconductor substrate including a first and second face, where the substrate has a concentration of majority carriers which is sufficient to allow high-quality polarisation,
a nucleation layer suitable for growing nanowires,
several nanowires the bases of which are in contact with the nucleation layer, where the nanowires include an active zone suitable for converting from an electrical signal into electromagnetic radiation, or vice versa,
a first electrical contact fitted on the second face of the substrate to polarise the substrate,
a second electrical contact in contact with each of the nanowires at their end opposite the base.

Thus, with such a structure, polarisation of the active zone of each of the nanowires is obtained by applying a difference of potential between the first and second contact. In operation, and for an optoelectronic structure, this polarisation of the active zone allows conversion from an electrical signal into electromagnetic radiation, or vice versa.

Although such a structure allows the means of the first and second electrical contact to polarise the active zone of each of the nanowires, it nonetheless involves non-negligible electrical losses in the substrate/nucleation layer/nanowires interfaces.

The materials forming the substrate, the nucleation layer and the base of the nanowires are indeed generally semiconductors of different natures, and form a heterostructure at each interface. Such a type of interface generally has high interface resistance.

This is particularly so when the nanowires have a base made from a semiconducting nitride. Indeed, for this type of nanowire, the nucleation layer is made from aluminum nitride (AlN), which is a wide-band gap semiconductor (where the energy of its forbidden band is higher than 6 eV), which has the properties of a “semi-insulator”. The substrate/nucleation layer and nucleation layer/nanowires layer therefore have a high interface resistance with such material forming the nucleation layer. The consequence is that the polarisation of the base of each nanowire by the substrate/nanowire interface leads to substantial electrical losses, principally relating to the presence of the nucleation layer.

Such a structure therefore requires higher polarisation voltages to compensate for the losses in this interface, and is less efficient since the voltages are reduced by the said losses.

It may be noted that in the case of a structure of the photovoltaic type, although the active zone does not require polarisation, the first and second contacts are present for connecting the structure in order to collect the energy produced in the active zone, and the problem of the losses in the substrate/nanowires interface is therefore also present for a structure of the photovoltaic type.

### SUMMARY OF THE INVENTION

The present invention seeks to remedy this disadvantage.

One aim of the invention is therefore to provide a nanowire-based optoelectronic semiconductor structure including a nucleation layer, where the structure has an interface resistance between the substrate and each of the nanowires which is lower compared to a structure of the prior art.

One more particular aim of the invention is therefore to provide a nanowire-based optoelectronic semiconductor structure including a nucleation layer having a forbidden energy band higher than 5 eV, where the structure has an interface resistance between the substrate and each of the nanowires which is lower compared to a structure of the prior art including such a nucleation layer.

Another aim of the invention is to provide a nanowire-based optoelectronic semiconductor structure which optimises dissipation of the heat produced by the active zones of each of the nanowires while the structure is in operation.

To this end, the invention concerns an optoelectronic semiconductor structure including:
a semiconductor substrate having a first and second face,
a nucleation layer in contact with the first face of the substrate,
a nanowire in contact with the nucleation layer,

where the nucleation layer is formed from at least one pad and covers the first face of the substrate over a portion of the first face, called the “nucleation” face, where the portion of the first face which is not covered by the nucleation layer is called the “free” portion, where the structure also includes a conducting layer in contact with the free portion of the substrate, and where the said conducting layer is also in contact with the nanowire on the perimeter of the nanowire.

Due to its contact both with the substrate and the nanowire such a conducting layer enables the nanowire to be polarised in parallel with the contact provided by the nucleation layer. Thus, for a contact provided by the nucleation layer through substrate/nucleation layer/nanowire interfaces with high electrical losses, polarisation of the nanowire is essentially obtained through the conducting layer and the electrical losses relating to the substrate/conducting layer and conducting layer/nanowire interfaces are reduced accordingly. This results in lower electrical losses for the substrate/nanowire interface compared to a structure of the prior art in which polarisation is provided solely by the nucleation layer.

In addition, such a conducting layer has, due to the thermal conduction by these majority carriers, thermal conduction properties which enable a proportion of the heat produced by the active zones while the structure is in operation to be dissipated.

The invention concerns more particularly a structure in which the nucleation layer has a forbidden energy band higher than 5 eV. The nucleation layer can be a semiconductor layer.

The conductive layer can be in contact with the nanowire on its entire perimeter.

The free portion of the first face can be recessed relative to the nucleation portion, over a recess height which is between 1 nm and 5 μm, and where the said recess height is preferentially between 1 nm and 500 nm.

Such a recess of the free portion of the first face enables the portion of the conduction layer which can be in contact with the substrate to be increased, where this conduction layer can be in contact with the substrate over the free portion and over the walls created by the recess of the free portion. Thus, the electrical interface between the conducting layer and the substrate is optimised with a low contact resistance. As the contact resistance between the nanowire and the conducting layer is also low thanks to the contact of the conducting layer on the perimeter of the nanowire, the resulting electrical interface between the nanowire and the substrate is optimized and the corresponding access resistance is reduced in comparison to a semiconductor structure which does not comprise such recess of the free portion of the first face.

The nanowire can cover roughly the entire nucleation layer.

The area of the nucleation portion of the first face is thus reduced as far as possible, giving an area of the free portion which is maximised. By this means a maximum value for the area of the first face on which the conduction layer can be in contact is obtained.

Since the nucleation layer can be formed from a pad corresponding to the nanowire, the nanowire covers the said pad.

The nanowire can be in contact on the nucleation layer in a plane which is roughly parallel to the first face of the substrate, having a maximum lateral dimension of the zone of the nanowire which is in contact with the conduction layer, where the conducting layer is in contact with the nanowire over a contact height which is at least equal to the maximum lateral dimension divided by four.

Such a contact height enables it to be guaranteed that the area of the conducting layer which is in contact with the periphery of the nanowire is sufficient to provide an optimised reduction of the interface resistance between the nanowire and the substrate compared to a structure of the prior art.

The transverse section of the nanowire in its zone which is in contact with the conducting layer can be roughly circular, hexagonal, triangular, square or of any other shape, where the maximum lateral dimension of such a nanowire is the diameter or width of such a transverse section.

The conducting layer can be principally made from a refractory material or from a refractory alloy.

Such a refractory material enables the properties of the conducting layer at the different annealing steps required to manufacture the structure to be guaranteed, without affecting its conductivity characteristics, and without any requirement to modify the manufacturing steps.

The conducting layer can be principally made from a material selected from the group containing titanium (Ti), tungsten (W), nickel (Ni) and alloys containing the said metals.

Such materials have the qualities required to form a conducting layer of satisfactory quality, and also have the advantage that they are able to form a silicide with the substrate, when the latter is made from silicon, thereby reducing the interface resistance between the substrate and conducting layer.

The structure can be a structure of a type selected from the group including structures able to emit electromagnetic radiation, structures able to receive electromagnetic radiation and to transform it into an electrical signal, and structures of the photovoltaic type.

Such structures have optimised efficiencies since the electrical losses in the substrate/nanowire interface are limited by the presence of the conducting layer.

The semiconductor structure may be intended to emit an electromagnetic radiation, where the structure includes:
a semiconductor substrate including a first and second face,
a nucleation layer, formed from at least one pad, on the first face of the covering substrate, where the said nucleation layer covers a portion of the first face, called the “nucleation” face, and where the remainder of the first face is called the “free” portion,
at least one semiconductor nanowire having an active zone able to emit electromagnetic radiation when it is polarised,
a conducting layer in contact with the first face of the substrate on its free portion, where a masking layer is in contact with the nanowire over a portion of its perimeter.

The semiconductor structure may be able to receive electromagnetic radiation, and to convert it into an electrical signal, where the structure includes:
a semiconductor substrate including a first and second face,
a nucleation layer in contact with the first face of the substrate,
a masking layer including at least one through aperture emerging in the nucleation layer,
at least one semiconductor nanowire in each of the apertures, in contact with the first face of the substrate, where the nanowire also has an active zone able to receive electromagnetic radiation, and to convert it into an electrical signal,

where the structure also includes a conducting layer in contact with the first face of the substrate on its free portion, where the masking layer is in contact with the nanowire over a portion of its perimeter.

The structure may include means of connection of the nanowire, where a first connection means is fitted to connect electrically to at least a portion of the substrate including the free portion of the first face, where a second connection means is fitted to connect the nanowire electrically at least in the end of the nanowire which is opposite the first face of the substrate.

The invention also concerns a method of manufacture of an optoelectronic semiconductor structure including at least one semiconductor nanowire, where the said method includes the steps consisting in:
providing a semiconductor substrate having a first and second face,
forming a nucleation layer, formed from at least one pad, in contact with a first face of the substrate over a portion, called the “nucleation” portion, of this same first face, and where the portion of the first face which is not covered by the nucleation layer is called the “free” portion,
forming a conducting layer in contact with the free portion of the first face,
forming at least one nanowire with a portion of the nanowire, called the “contact” nanowire, which is in contact with the pad of the nucleation layer, and where the nanowire is in contact with the conducting layer.

Due to the step of formation of the conduction layer, such a method enables a nanowire-based structure to be manufactured which includes a nucleation layer, which has a reduced operating voltage compared to a structure of the prior art not including a conduction layer.

A step of etching of the free portion of the first face may also be included, such that the free portion of the first face is recessed relative to the nucleation portion of this same first face, where the said recess height is between 1 nm and 5 μm and is preferentially between 1 nm and 500 nm.

Such a step of etching of the free portion enables a higher contact area to be provided when the conduction layer is formed, thus making it possible for the structure obtained by the method to have a lower interface resistance compared to a structure the manufacturing method of which does not involve such an etching step.

The step of formation of the nucleation layer may include the sub-steps consisting in:
forming a nucleation layer over the entire first face,
selectively etching a portion of the nucleation layer so as to release the free portion of the first face of the substrate.

Such sub-steps allow the formation of the nucleation layer over the entire first face of the substrate with an alteration of the free portion after the formation of the nucleation layer.

The step of etching of the free portion of the first face and the sub-step of selective etching of a portion of the nucleation layer can be undertaken during a single etching step.

Such an etching step allows, in a single step, firstly the nucleation layer to be shaped by releasing the free portion, and secondly the recess of the free portion to be formed, allowing the contact between the free portion and the conducting layer to be optimised during the step of formation of the conducting layer.

The step of formation of at least one nanowire may include the sub-steps consisting in:
forming a layer called the “masking” layer on the conducting layer,
forming an aperture in the masking layer and in a portion of the conducting layer, where the said aperture emerges in the nucleation layer to reveal the pad,
forming a nanowire by selective growing on the pad of the nucleation layer in which the aperture emerges.

Such a step of formation of the nanowire allows, for a conduction layer which is not suitable for selective growing of the nanowire, a nanowire to be formed by presenting a peripheral contact with the conduction layer.

The step of formation of at least one nanowire may include the sub-steps consisting in:
forming an aperture in the conducting layer, where the said aperture emerges in the nucleation layer to reveal the pad,
forming a nanowire by selective growing on the pad of the nucleation layer.

Such a step of formation of the nanowire enables a nanowire to be formed which has a peripheral contact with the conduction layer, without requiring the prior formation of a masking layer, and where the conduction layer is able to allow selective growing of the nanowire on the nucleation layer.

The step of formation of at least one nanowire may include the sub-steps consisting in:
forming, before the step of etching of the free portion of the first face and of a portion of the nucleation layer, a buffer layer on the nucleation layer, where the said buffer layer is etched with the nucleation layer and the free portion of the first face,
forming, after the step of formation of the conducting layer, of a layer called the “masking” layer on the conducting layer,
forming an aperture in the masking layer and in a portion of the conducting layer, where the said aperture emerges in the buffer layer,

forming a nanowire by selective growing on the portion of the buffer layer in which the aperture emerges.

Formation of a buffer layer on the nucleation layer before the step of formation of the nanowire, where the said nanowire includes the portion of the corresponding buffer layer, enables a nanowire of high quality to be provided. Indeed, such a nanowire has a base formed from the said portion of buffer layer which has the quality of a “2D” layer, where the remainder of the nanowire is also of high quality, since it has been formed from a particularly suitable layer, namely the buffer layer

The step of formation of the nanowire includes the sub-steps consisting in:
forming a first lengthways zone of the nanowire, where the said zone is roughly transverse to the first face of the substrate, and where the said first zone has a composition which is able to inhibit the lateral growth of the materials intended to form the remainder of the nanowire,
forming the remainder of the nanowire.

Since the step of formation of the nanowire is a step of formation of a micro- or nanowire made of semiconducting nitride, such as GaN, the said first zone may include silicon so as to modify the said first zone to inhibit the lateral growth of the materials intended to form the remainder of the nanowire.

### BRIEF DESCRIPTION OF THE ILLUSTRATIONS

The present invention will be better understood on reading the description of example embodiments given purely as an indication and in no way restrictively, making reference to the appended illustrations in which:

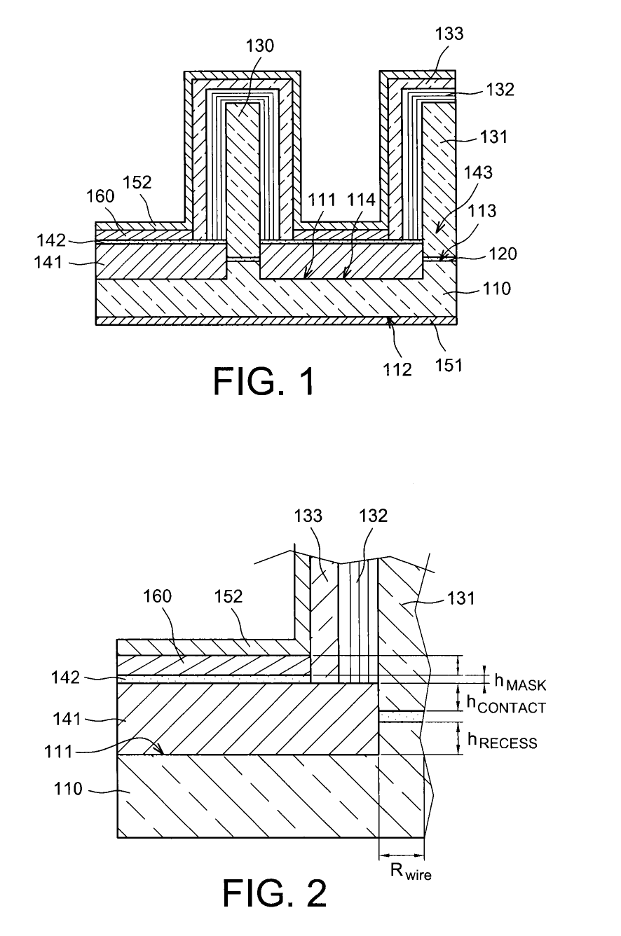

FIG. 1 illustrates an example of a semiconductor structure according to a first embodiment,

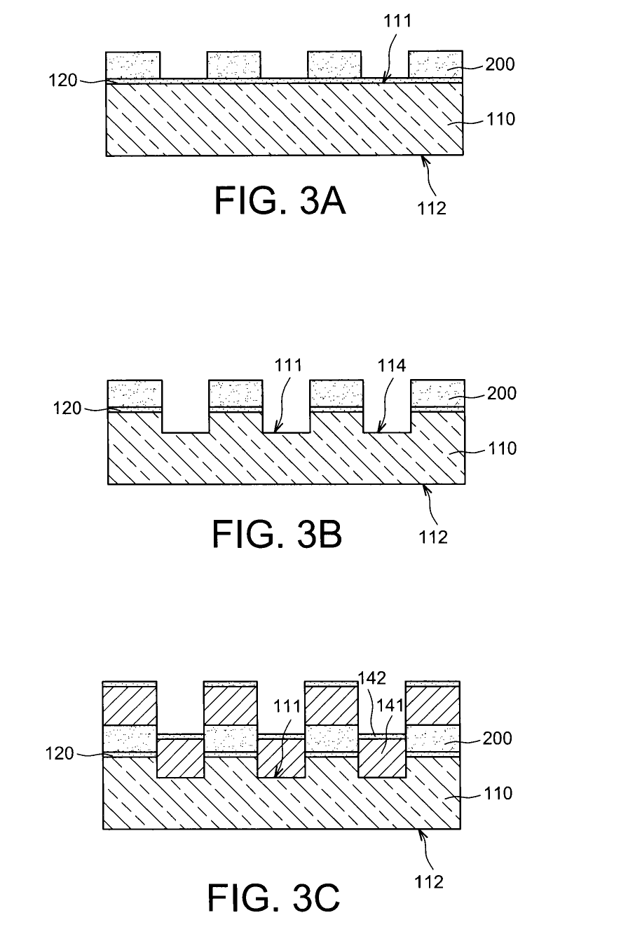

FIG. 2 illustrates, in a close-up view of a portion of the structure of FIG. 1, the different characteristic dimensions of the said structure,

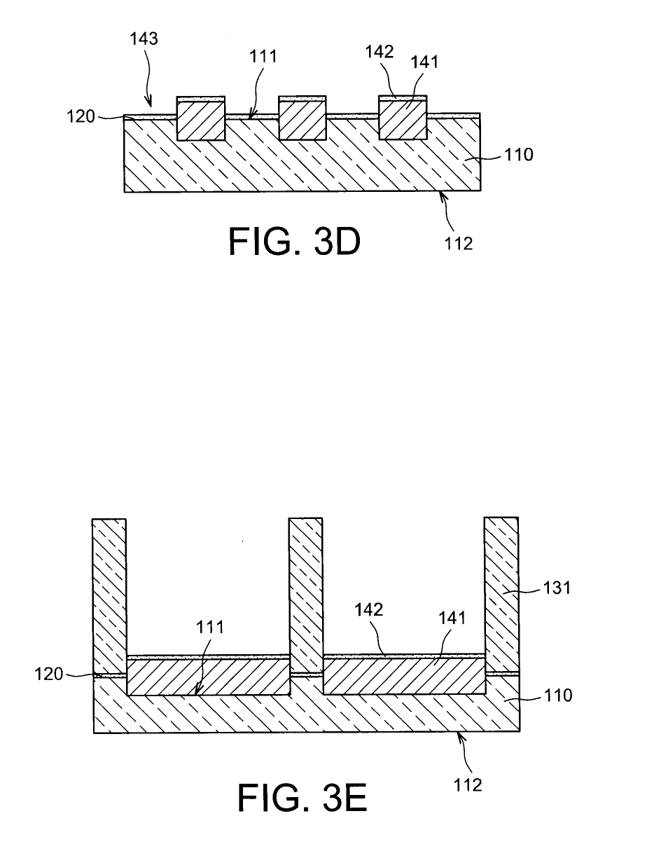

FIGS. 3A to 3H illustrate the different steps of manufacture of the semiconductor structure illustrated in FIG. 1,

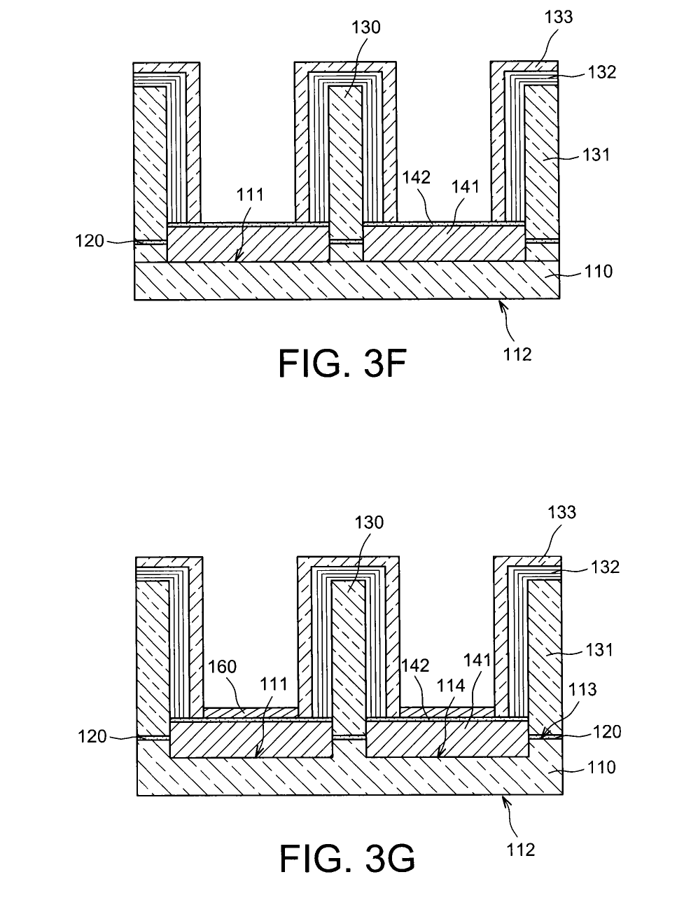

FIG. 4 illustrates a semiconductor structure according to the second embodiment in which the semiconductor structure includes a buffer layer,

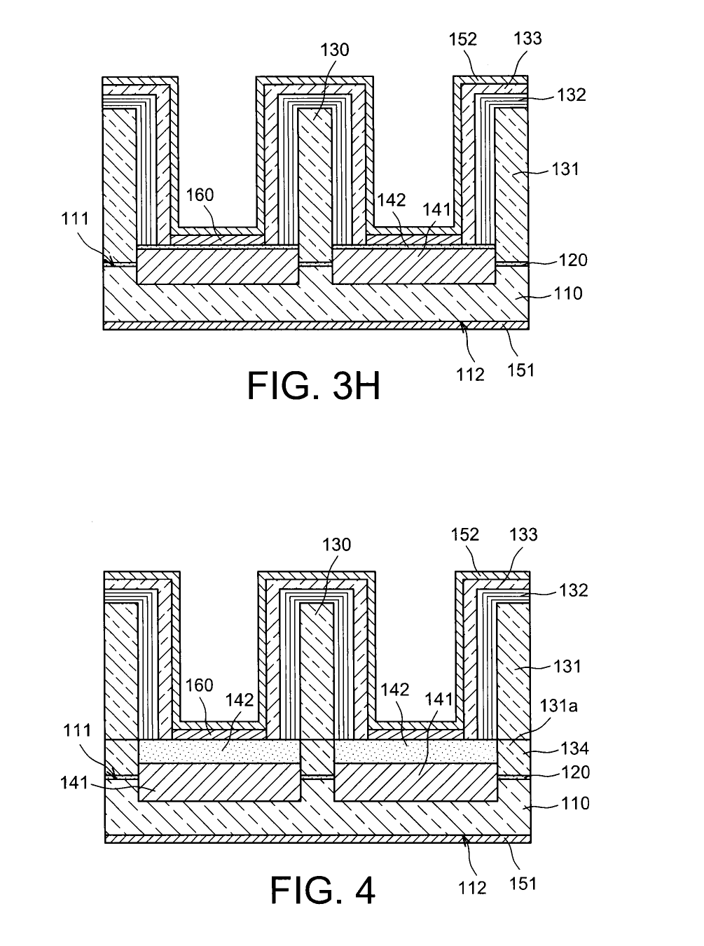

FIG. 5 illustrates a semiconductor structure according to a third embodiment in which each of the nanowires includes an active zone of the axial type,

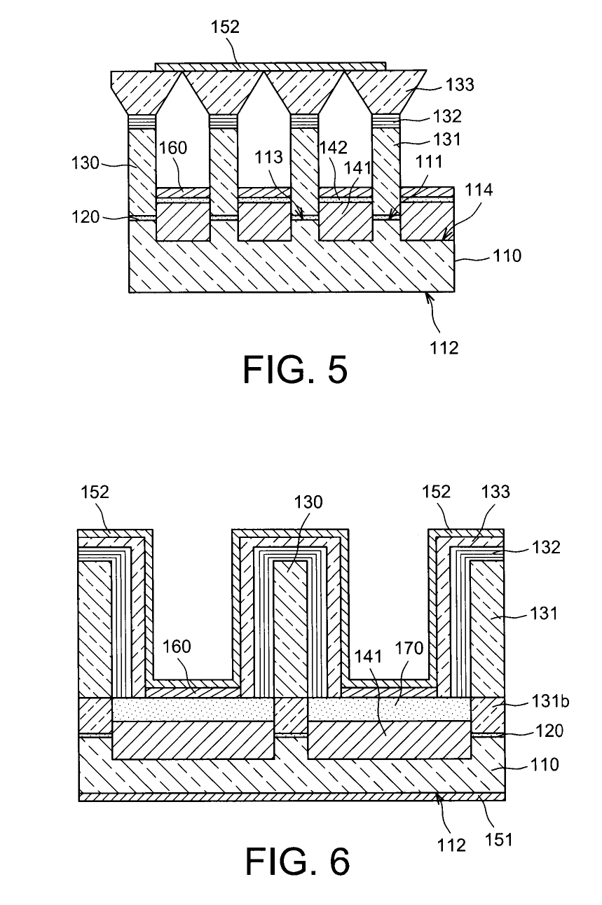

FIG. 6 illustrates a semiconductor structure according to a fourth embodiment in which the structure includes no masking layer, and in which the contact portion of each of the nanowires includes in its zone of contact with the nucleation layer a first zone able to inhibit lateral growth.

Identical, similar or equivalent parts of the various figures have the same numerical references, to make it easier to go from one figure to another.

The various parts represented in the figures are not necessarily represented at a uniform scale, in order to make the figures more readable.

The various possibilities (variants and embodiments) must be understood as not being mutually exclusive, and being able to be combined with one another.

### DETAILED ACCOUNT OF PARTICULAR EMBODIMENTS

FIG. 1 illustrates schematically a semiconductor structure 100 according to a first embodiment of the invention. Structure 100 illustrated in FIG. 1 is more specifically a semiconductor structure suitable for a particular application which is the emission of electromagnetic radiation the wavelength of which is within the visible range, i.e. between 400 and 800 nm.

The characteristics and values which are mentioned in the remainder of this document, when mention is made of the particular application, concern only this application and do not restrict in any sense the invention's fields of application.

Such a semiconductor structure 100 includes:
a semiconductor substrate 110 having a first and second face 111, 112,
a nucleation layer 120, formed of pads, in contact with the first face of the substrate and covering a portion 113 of first face 111, called the “nucleation” face, where the remainder 114 of the first face is called the “free portion”,
a conducting layer 141 in contact with first face 111 of substrate 110,
a masking layer 142 in contact with the surface of conducting layer 141 which is opposite substrate 110, where the said conducting 141 and masking 142 layers include apertures 143 emerging at the pads of nucleation layer 120,
nanowires 130, each of which is in contact with a pad of nucleation layer 120 through, in the case of each, corresponding aperture 143, where the said nanowires extend through conducting layer 141 and masking layer 142, and where each of nanowires 130 has an active zone 132,
a reflecting layer 160 formed on masking layer 142 and able to reflect electromagnetic radiation emitted by active zones 132 of nanowires 130,
a first electrical contact 151 in electrical contact with second face 112 of substrate 110,
a second electrical contact 152 in electrical contact with each of nanowires 130.

The term “semiconductor nanowires” is understood to mean, above and throughout this document, semiconductor structures having three dimensions, two of which are the same order of magnitude of between 5 nm and 2.5 μm, and where the third dimension is equal at least to 2 times, or 5 times, or more preferentially 10 times, the greater of the two other dimensions.

Radius R_{wire} of each of nanowires 130 can be defined as the maximum lateral dimension of apertures 143 divided by two.

FIG. 2 illustrates the values of the different thicknesses and heights of the layers comprising the structure according to the first embodiment.

Substrate 110 is a semiconductor substrate suitable for growing nanowires 130. It is roughly flat in shape.

Substrate 110 is a semiconductor substrate which allows conduction of the majority carriers, such as a substrate made of silicon Si, silicon carbide SiC, zinc oxide ZnO or germanium Ge, or is a metal substrate.

Substrate 110 has a first type of conductivity. To restrict the electrical losses relating to the electrical resistance between substrate 110 and nanowires 130, substrate 110 has a high concentration of majority carriers.

Thus, according to the particular application illustrated in FIG. 1, where substrate 110 is a silicon substrate the type of conductivity of which has majority carriers which are electrons, the majority carriers concentration can be chosen to be of the order of 10¹⁹ cm⁻³.

Substrate 110 has on its first face 111 the free portion 114 which is recessed relative to nucleation portion 113. Nucleation portion 113 and free portion 114 are, respectively, the portions of the first face 111 of substrate 110 which is in contact with nucleation layer 120, and those which are not.

The depth of recess h_{recess}, as illustrated in FIG. 2, of free portion 114 relative to the nucleation portion is between 0 and 5 μm, and is preferably between 1 nm and 500 nm.

The substrate has first electrical contact 151 on its second face.

First electrical contact 151 has the form of a metal layer able to polarise substrate 111. First electrical contact 151 is, for the particular application, made of a metal able to form a silicide with silicon. The first contact forms a first means of polarisation able to polarise the substrate.

To limit the concentration of crystalline faults of nanowires 130, structure 100 includes nucleation layer 120 which is formed from a material suitable for growing nanowires 130. Nucleation layer 120 enables a portion of the crystal lattice difference which may exist between the material constituting substrate 110 and the material of the portion of nanowires 130 in contact with first face 111 of substrate 110 to be reduced. Concerning the portion of nanowires 130 in contact with substrate 110 which is made of a semiconducting nitride, such a material is one such as gallium nitride (GaN) or aluminum nitride (AlN).

The nucleation layer 120 is formed from a material with a forbidden energy band higher than 5 eV such as a nitride or an oxide. For example, the nucleation layer 120 can be formed from aluminum nitride (AlN), boron nitride (BN), sapphire (Al2O3), an boron oxide (B₂O₃) or an oxidized nitride such as an oxidized aluminum nitride (AlON) or an oxidized boron nitride (BON). Such materials are particularly suited for the growth of nanowires in which the contact portion 131 is formed from a gallium nitride (GaN) or a zinc oxide (ZnO)

Nucleation layer 120 is formed of pads.

The term of “pads” is understood to mean, above and throughout this document, an area of the nucleation layer separate from the other area with lateral dimensions that are relatively low, regarding the ones of the surface on which the nucleation layer is, and that are on the same order of one each other.

Here, the lateral dimensions of each pads are adjusted for the growth a nanowire, and thus, corresponds to the two lowest dimensions of the nanowire. So, in the case of a 50 nm diameter nanowire, the nucleation layer pad is a 50 nm diameter pad.

Conducting layer 141 is in contact with first face 111 of substrate 110 on its free portion 114. Conducting layer 141 is roughly flat in shape, and apertures 143 are partially made through conducting layer h_{contact}.

Conducting layer 141 is a layer made of a conductive material. Conducting layer 141 is preferentially made of a refractory material.

If substrate 110 is made of silicon, such as, for example, the case of the particular application, the material of conducting layer 141 is preferentially a material forming a silicide with silicon. In this latter case the material from which conducting layer 141 is made may be chosen from the group including titanium (Ti), tungsten (W), nickel (Ni), cobalt, Pt, Pd and the alloys containing the said metals.

The thickness of conducting layer 141 is greater than the recess depth h_{recess} of free portion 114 of first face 111 of substrate 110; conducting layer 141 thus protrudes from first surface 111 over a height called the “contact” height h_{contact}, as illustrated in FIG. 2. The value of contact height h_{contact} is equal to the difference between the thickness of conducting layer 141 and recess depth h_{recess}.

The contact height is preferably greater than or equal to the nanowires radius R_{wire} divided by two. Such a dimension enables a height to be provided over which conducting layer 141 is in contact with each of nanowires 130, the area of which is equal to the area of the base of nanowires 130.

Masking layer 142 extends to the surface of conducting layer 141 which is opposite substrate 110. Masking layer 142 is roughly flat in shape, and the portion of each of apertures 143 which is not made in conducting layer 141 is made all the way through masking layer 142.

Masking layer 142 is produced from a material on which the element or elements comprising nanowires 130 are not deposited during epitaxial growth. The material forming masking layer 142 is preferentially an insulator. Masking layer 142 may be, for nanowires 160, made of gallium nitride (GaN), silicon nitride (Si₃N₂), or silicon dioxide (SiO₂). Thickness hₘₐₛₖ of the masking layer, as illustrated in FIG. 2, may be between 1 nm and 1 μm.

Thus, conducting layer 141 and masking layer 142 have apertures 143 each of which accommodates one of nanowires 130.

Each aperture 143 emerges at a pad of nucleation layer 120.

Each aperture 143 has a transverse section relative to the conducting layer which may be roughly circular, hexagonal, triangular, square or of any similar shape. The maximum lateral dimension of such an aperture, which is equal to that of the corresponding nanowire, is the diameter or width of such a transverse section.

Each of nanowires 130 is a semiconductor structure lengthened in the direction roughly perpendicular to first face 111 of substrate 110. Each micro- or nanowire 130 is of a general extended cylindrical shape. Radius R_{wire}, as illustrated in FIG. 2, of each of nanowires 130 is chosen according to the application of semiconductor structure 100 containing them. For example, in the particular application illustrated in FIG. 1, the radius of each nanowire 130 is approximately 500 nm.

The height of each of nanowires 130 is greater than at least 2 times, or possibly 5 times or 10 times, the diameter of nanowire 160. The height of each of nanowires 130 may be between 100 nm and 30 μm.

Each nanowire 130 includes a portion, called the “contact” portion, in contact with nucleation layer 120, an active zone 132 in contact with contact portion 131 and a portion 133, called the “polarisation” portion, in contact with active zone 132.

Contact portion 131 of each nanowire 130 is in contact with the first face of substrate 110. Contact portion 131 of each nanowire 130 is also in contact on its entire perimeter with the conducting layer 141. The electrical contact between the conducting layer 141 and the contact portion 131 of each nanowire 130 is performed, as already been explained, on the thickness of the conducting layer that corresponds to the contact height h_{contact}.

Contact portion 131, including the base of corresponding nanowire 130, as illustrated in FIG. 1, represents most of corresponding nanowire 130.

Each of contact portions 131 is principally made from a direct-band gap semiconductor material of the first type of conductivity. The semiconductor material comprising contact portion 131 of each of nanowires 130 is modified according to the application of semiconductor structure 100 including nanowires 130. Thus, depending on the sought applications, the material comprising each of contact portions 131 may be selected from the group including gallium nitride (GaN), aluminum nitride (AlN), indium nitride (InN), the indium-gallium nitrides of the InₓGa₁₋ₓN type, and the zinc oxide (ZnO).

It is possible to notice, that the invention is particularly adapted for nanowires comprising a contact portion in aluminum nitride AlN or in zinc oxide ZnO.

For the particular application illustrated in FIG. 1, the semiconductor material comprising the contact portion of each of the nanowires is gallium nitride (GaN).

Thus, in the particular application illustrated in FIG. 1, each contact portion 131 is made of gallium nitride (GaN) and has a majority carrier concentration which is between 1·10¹⁸ and 5·10¹⁸ cm⁻³.

Each of active zones 132 is in contact with contact portion 131 of corresponding nanowire 130. Each active zone 132 is a layer covering contact portion 131 over a portion of the perimeter and over the end of corresponding contact portion 131, where the said end of contact portion 131 is the one opposite nucleation layer 120. Such a configuration of active zones 132 in which they are in contact with, simultaneously, one end and the perimeter of corresponding contact portion 131, is called a “shell” configuration.

Each active zone 132 includes a semiconductor junction. Active zone 132, for an application in which structure 100 is suitable for the emission of electromagnetic radiation, may, in order to increase the emission efficiency of each of nanowires 130, include confinement means, such as multiple quantum wells.

In the particular illustration illustrated in FIG. 1, active zone 132 is formed from gallium and indium nitride in the form InₓGaₓ₋₁N. According to this particular application, the multiple quantum wells are obtained by alternating through active zone 132 two different relative compositions of indium In and gallium Ga.

Since active zones 132 as such are well known to the skilled man in the art they will not be described in greater detail in this document.

Each active zone 132 is in contact at its external perimeter with polarisation portion 133 of corresponding nanowire 130.

Polarisation portions 133 enable corresponding nanowire 130 to be contacted.

Polarisation portions 133 are preferably comprised principally of a direct-band gap semiconductor material. Each of polarisation portions 133 has a conductivity of the second type.

For application of the invention illustrated in FIG. 1, each of polarisation portions 133 has a majority carrier concentration which is between 1·10¹⁷ and 1·10¹⁸ cm⁻³.

Each polarisation portion 133, to allow polarisation of each of nanowires 130, is in contact with second contact 152.

Second contact 152 is able both to allow polarisation of each of nanowires 130 in their polarisation portion 133, and to allow the electromagnetic radiation emitted or received by nanowires 130 to pass through.

Second contact 152 is a layer of a transparent, or partially transparent, conductor material, of the wavelength emitted or received by the structure and which is able to provide a contact with a semiconductor material having the second type of conductivity. Thus, the layer of which second contact 152 is formed may be nickel-gold (Ni—Au), indium-tin oxide (ITO) or any stack of these materials (such as Ni/ITO).

Second contact 152 forms a second means of polarisation able to polarise a proportion of each of nanowires 130.

Structure 100 also includes, positioned between masking layer 142 and the layer constituting second contact 152, a reflecting layer 160. Such a reflecting layer 160 is a layer able to reflect the electromagnetic radiation at the wavelength for which structure 100 is intended to operate.

In the particular application illustrated in FIG. 1, the material of reflecting layer 160 is silver (Ag) or aluminum (Al), the thickness of the upper layer of which is 50 nm and preferentially greater than 100 nm.

FIGS. 3A to 3H illustrate a method of manufacture of such a structure 100. Such a manufacturing method includes the steps consisting in:
providing a semiconductor substrate 110 having a first and second face 111, 112,
forming a nucleation layer 120 in contact on first face 111 of substrate 110, with the said nucleation layer,
applying a photosensitive resin 200, and undertaking, as illustrated in FIG. 3A, a lithography operation so as to remove the portion of the resin corresponding to free portion 114 of first face 111,
etching, as illustrated in FIG. 3B, the zones not protected by resin 200 so as to release these zones, corresponding to the free portion of the first face, of the nucleation layer, and in order that the said zones may be recessed from the remainder of first face 111 by a recess depth h_{recess}, where this step also enables the pads of nucleation layer 120 to be revealed,
applying on free portion 114 and on the photosensitive resin the material constituting conducting layer 141,
depositing, as illustrated in FIG. 3C, masking layer 142 on conducting layer 141,
removing photosensitive resin 200 in such a way as also to remove conducting layer 141 which is not located in free portions 114;
Depositing masking layer 142 on the entire surface,
Depositing resin pads on the portions of conducting layer 141 located in free portions 114,
Etching masking layer 142 such that it emerges in nucleation layer 120.
forming contact portion 131 of nanowires 130 through apertures 143 and in contact with the corresponding pad of nucleation layer 120, where the contact portion is also in contact over a proportion of its periphery with conducting layer 141, see FIG. 3E,
forming, as illustrated in FIG. 3F, active zone 132 and polarisation portion 133 of each of nanowires 130, where such formation enables each nanowire to be formed,
depositing, as illustrated in FIG. 3G between each of nanowires 130 a reflecting layer 160 in contact with masking layer 142,
forming, as illustrated in FIG. 3H, second contact 152 on the polarisation portion of nanowires 130 and reflecting layer 160.

In the step of deposition of the reflecting layer, the reflecting layer is preferentially deposited in a non-conformal manner. According to this possibility, the portion of layer 160 in contact with masking layer 142 is then protected with resin, in order to etch the portion of layer 160 deposited at the upper end of the nanowire. FIG. 4 illustrates a structure 100 according to a second embodiment. A structure 100 according to this second embodiment is differentiated from a structure 100 according to the first embodiment in that each nanowire 130 includes in its contact portion 131a zone 131a formed from a 2D layer called a “buffer” layer.

The buffer layer is a layer formed prior to the growth on nucleation layer 120 made from a material which is particularly suitable both for growing contact portion 131 of nanowires 130 and forming an electrical interface with this same portion of nanowires 130 which has lower resistance. The material constituting buffer layer 134 is preferentially chosen to be roughly identical to that of the remainder of contact portion 131 of nanowires 130.

Buffer layer 134 is between 300 nm and 5 μm thick.

Free portion 114 of first face 111 is recessed relative to the remainder of first face 111 over a recess depth h_{recess} which is greater than the thickness of buffer layer 134.

In this second embodiment, contact height h_{contact} is equal to the height over which conducting layer 141 is in contact with zone 131a of the nanowire formed in the buffer layer.

A method of manufacture of a structure 100 according to this second embodiment is differentiated from a method of manufacture according to the first embodiment in that it includes, between the step of formation of the nucleation layer and the step of application of the photosensitive resin, a step of formation of the buffer layer.

FIG. 5 illustrates a structure 100 according to a third embodiment. A structure 100 according to this third embodiment is differentiated from a structure 100 according to the first embodiment in that each active zone 132 is an active zone of the axial type.

Such active zones 132 are differentiated from an active zone according to the two embodiments described above in that they are extensions of corresponding contact portions 131, and in that the contact between the said active zones and corresponding contact portions 131 is only at the end of contact portion 131.

According to this same possibility, each polarisation portion 133 is also an extension of corresponding contact portion 131 and of corresponding active zone 132, where the contact between each polarisation portion 133 and corresponding active zone 132 is only at the end of active zone 132.

The method of manufacture of a structure 100 according to this possibility is differentiated from the method of manufacture of a structure 100 according to the first embodiment only by the steps of formation of the nanowires 130 which are suitable for the formation of nanowires 130 including an active zone 132 of the axial type.

FIG. 6 illustrates a structure 100 according to a fourth embodiment. Such a structure 100 is differentiated from a structure 100 according to the first embodiment in that contact portion 131 of each of nanowires 130 includes a first zone 131a which is able to inhibit the lateral growth of the materials which form the remainder 132, 133 of nanowire 130. A structure 100 according to the fourth embodiment is also differentiated from a structure according to the first embodiment in that it does not include a masking layer 142, and in that it includes an insulation layer 170 positioned between conducting layer 141 and reflecting layer 160.

In this embodiment nanowires 130 are principally formed from a semiconducting nitride. First zone 131b is a zone of each of nanowires 130 which includes on its perimeter an inhibition layer (not illustrated), as described in the French patent application registered as number 1152926, formed of silicon nitride. This inhibition layer several nanometres thick enables the lateral growth to be inhibited on the perimeter of the first zone of each nanowire, thus preventing the growth of active zone 132 and of polarisation portion 133 in this zone. Due to its small thickness, the inhibition layer does not significantly affect the contact between conduction layer 141 and the perimeter of the contact portion of nanowire 130.

Insulation layer 170 is a layer made from a dielectric material, such as silicon dioxide SiO₂, which is traditionally used to electrically insulate conducting layers in the microelectronics field. The thickness of insulating layer 170 is such that it is able to insulate electrically from one another conducting layer 141 and reflecting layer 160, where the latter is in direct contact with second electrical contact 152.

The method of manufacture of a structure 100 according to this fourth embodiment is differentiated from the method of manufacture of a structure 100 according to the first embodiment in that it does not include the step of formation of masking layer 142, in that the step of formation of contact portion 131 includes a sub-step consisting in depositing a semiconducting nitride including a proportion of silicon so as to form first zone 131a of contact portion 131, and in that it includes a step consisting in forming insulation layer 170 on conducting layer 141 before the step of formation of reflecting layer 160.

1. An optoelectronic semiconductor structure including:
a semiconductor substrate having a first and second face,
a nucleation layer in contact with the first face of the substrate,
a nanowire in contact with the nucleation layer,
where the said structure is characterised in that the nucleation layer is formed from at least one pad and covers the first face of the substrate over a portion of the first face, called the “nucleation” face, where the portion of the first face which is not covered by the nucleation layer is called the “free” portion, where the structure also includes a conducting layer in contact with the free portion of the substrate, and where the said conducting layer is also in contact with the nanowire on the perimeter of the nanowire (130).

2. A structure according to claim 1, in which the nucleation layer has a forbidden energy band higher than 5 eV.

3. A structure according to claim 1, in which the nucleation layer is made from a wide-band gap semiconductor with a forbidden energy band higher than 5 eV.

4. A structure according to claim 1, in which the free portion of the first face is recessed relative to the nucleation portion, over a recess height (h_{recess}) which is between 1 nm and 5 μm, and where the said recess height (h_{recess}) is preferentially between 1 nm and 500 nm.

5. A structure according to claim 1, in which the nanowire covers roughly the entire nucleation layer.

6. A structure according to claim 1, in which the nanowire is in contact on the nucleation layer in a plane which is roughly parallel to the first face of the substrate, having a maximum lateral dimension of the zone of the nanowire which is in contact with the conduction layer, where the conducting layer is in contact with the nanowire over a contact height which is at least equal to the maximum lateral dimension divided by four.

7. A structure according to claim 1, in which the conducting layer is made principally from a refractory material or a refractory alloy.

8. A structure according to claim 1, in which the conducting layer is principally made from a material selected from the group containing titanium (Ti), tungsten (W), nickel (Ni) and alloys containing the said metals.

9. A semiconductor structure according to claim 1, in which the structure is a structure of a type selected from the group including structures able to emit electromagnetic radiation, structures able to receive electromagnetic radiation and to transform it into an electrical signal, and structures of the photovoltaic type.

10. A semiconductor structure according to claim 1, in which the structure further comprises a first electrical contact in contact with the substrate and a second electrical contact in contact with the nanowire on a extremity of the nanowire that is in the opposite of the substrate, in such way to allow a polarization of the nanowire.

11. A method of manufacture of an optoelectronic semiconductor structure including at least one semiconducting nanowire, where the said method includes the steps consisting in:
providing a semiconductor substrate having a first and second face,
forming a nucleation layer, formed from at least one pad in contact with a first face of the substrate over a portion, called the “nucleation” portion, of this same first face, and where the portion of the first face which is not covered by the nucleation layer is called the “free” portion,
forming a conducting layer in contact with the free portion of the first face,
forming at least one nanowire with a portion of the nanowire, called the “contact” nanowire, which is in contact with the nucleation layer, and where the nanowire is in contact with the conducting layer over its perimeter.

12. A method of manufacture according to claim 11, in which a step is included of etching of the free portion of the first face (born one), such that the free portion is recessed by a recess height (h_{recess}) relative to the nucleation portion and of this same first face, and where the said recess height (h_{recess}) is between 1 nm and 5 μm and is preferentially between 1 nm and 500 nm.

13. A method of manufacture according to claim 11, in which the step of formation of the nucleation layer includes the sub-steps consisting in:
forming a nucleation layer over the entire first face,
selectively etching a portion of the nucleation layer so as to release the free portion of the first face (111) of the substrate.

14. A method of manufacture according to claim 12, in which the step of etching of the free portion of the first face and the sub-step of selective etching of a portion of the nucleation layer can be undertaken during a single etching step.

15. A method of manufacture according to claim 11, in which the step of formation of at least one nanowire includes the sub-steps consisting in:
forming a layer called the “masking” layer on the conducting layer,
forming an aperture in the masking layer and in a portion of the conducting layer, where the said aperture emerges in the nucleation layer to reveal the pad,
forming a nanowire by selective growing on the pad of the nucleation layer in which the microwire or nanowire emerges.

16. A method of manufacture according to claim 11, in which the step of formation of at least one nanowire includes the sub-steps consisting in:
forming an aperture in the conducting layer, where the said aperture emerges in the nucleation layer to reveal the pad,
forming a nanowire by selective growing on the pad of the nucleation layer.

17. A method of manufacture according to claim 14, in which the step of formation of at least one nanowire includes the sub-steps consisting in:
forming, before the step of etching of the free portion of the first face and of a portion of the nucleation layer, a buffer layer on the nucleation layer, where the said buffer layer is etched with the nucleation layer and the free portion of the first face,
forming, after the step of formation of the conducting layer, a layer called the “masking” layer on the conducting layer,
forming an aperture in the masking layer and in a portion of the conducting layer, where the said aperture emerges in the buffer layer,
forming a nanowire by selective growing on the portion of the buffer layer in which the aperture emerges.
